(19) United States
(12) Patent Application Publication
(10) Pub. No.: US 2019/0096679 A1
(43) Pub. Date: Mar. 28, 2019

(54) GATE STACK PROCESSES AND STRUCTURES

(71) Applicant: GLOBALFOUNDRIES Inc., Grand Cayman (KY)

(72) Inventors: Balaji Kannan, Clifton Park, NY (US); Bala Haran, Watervliet, NY (US); Vimal K. Kamineni, Mechanicville, NY (US); Sungkee Han, Latham, NY (US); Neal Makela, Saratoga Springs, NY (US); Suraj K. Patil, Chino Hills, CA (US); Pei Liu, Clifton Park, NY (US); Chih-Chiang Chang, Clifton Park, NY (US); Katsunori Onishi, Somers, NY (US); Keith Kwong Hon Wong, Wappingers Falls, NY (US); Ruilong Xie, Niskayuna, NY (US); Chanro Park, Clifton Park, NY (US); Min Gyu Sung, Latham, NY (US)

(21) Appl. No.: 15/712,996

(22) Filed: Sep. 22, 2017

(51) Int. Cl. H01L 21/28; H01L 29/423; H01L 29/49; H01L 29/78

(52) U.S. Cl. CPC H01L 21/28114; H01L 29/4232; H01L 29/785; H01L 21/28088; H01L 29/4966

(57) ABSTRACT

Structures for a field-effect transistor and methods for forming a structure for a field-effect transistor. A gate cavity is formed in a dielectric layer that includes a bottom surface and a plurality sidewalls that extend to the bottom surface. A gate dielectric layer is formed at the sidewalls and the bottom surface of the gate cavity. A work function metal layer is deposited on the gate dielectric layer at the sidewalls and the bottom surface of the gate cavity. A fill metal layer is deposited inside the gate cavity after the work function metal layer is deposited. The fill metal layer is formed in direct contact with the work function metal layer.

### BACKGROUND

The present invention relates to semiconductor device fabrication and integrated circuits and, more specifically, to structures for a field-effect transistor and methods of forming a field-effect transistor.

Device structures for a field-effect transistor generally include a body region, a source and a drain defined in the body region, and a gate electrode configured to switch carrier flow in a channel formed during device operation in the body region. When a control voltage exceeding a designated threshold voltage is applied to the gate electrode, carrier flow occurs in an inversion or depletion layer in the channel between the source and drain to produce a device output current.

The gate electrode may include one or more work function metal layers and a fill layer composed of tungsten. The conventional process for forming the fill layer utilizes chemical vapor deposition and tungsten hexafluoride (WF₆) as a tungsten precursor source. The use of tungsten hexafluoride has associated deficiencies, such as corrosion of work function metals deriving from fluorine produced as a byproduct gas during tungsten chemical vapor deposition. Corrosion may be mitigated by covering the work function metal with a layer of a barrier metal that blocks the passage of fluorine during the formation of the tungsten fill layer. However, the barrier metal layer occupies a significant amount of space inside the gate cavity, which may elevate the electrical resistance of the gate electrode because the barrier metal may have a higher electrical resistivity than tungsten.

### SUMMARY

In embodiments of the invention, a method is provided for forming a field-effect transistor. The method includes forming a gate cavity in a dielectric layer that includes a bottom surface and a plurality of sidewalls extending to the bottom surface, and forming a gate dielectric layer at the sidewalls and the bottom surface of the gate cavity. A work function metal layer is deposited on the gate dielectric layer at the sidewalls and the bottom surface of the gate cavity. After the work function metal layer is deposited, a fill metal layer is deposited inside the gate cavity. The fill metal layer is formed in direct contact with the work function metal layer.

In embodiments of the invention, a structure is provided for a field-effect transistor. The structure includes a dielectric layer with a gate cavity having a bottom surface and a plurality of sidewalls that extend to the bottom surface. The structure further includes a gate dielectric layer at the sidewalls and the bottom surface of the gate cavity, a work function metal layer on the gate dielectric layer at the sidewalls and the bottom surface of the gate cavity, and a fill metal layer inside the gate cavity. The fill metal layer has a directly contacting relationship with the work function metal layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a device structure at successive stages of a processing method in accordance with embodiments of the invention.

FIGS. 6-8 are cross-sectional views of a device structure at successive stages of a processing method in accordance with embodiments of the invention.

### DETAILED DESCRIPTION

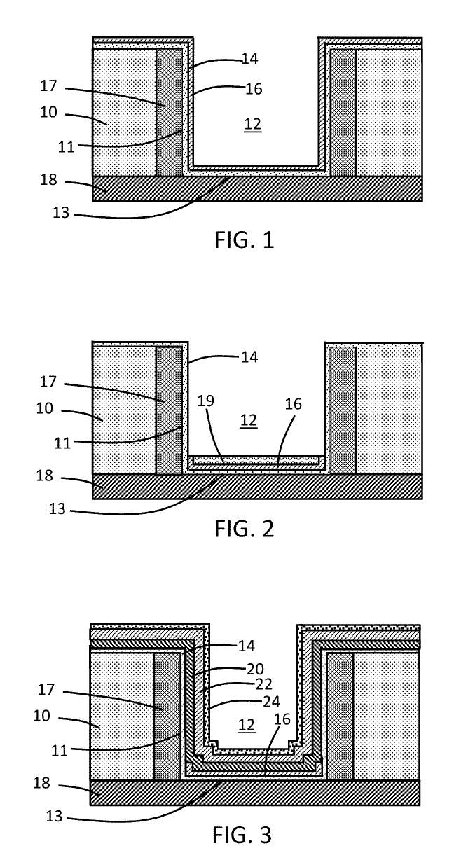

With reference to FIG. 1 and in accordance with embodiments of the invention, a gate dielectric layer 14 and a conductor layer 16 may be conformally deposited on the sidewalls 11 and bottom surface 13 of a trench or gate cavity 12 formed in one or more dielectric layers 10. The gate cavity 12 is defined between dielectric spacers 17 that are formed at the sidewalls 11. The dielectric spacers 17 may be formed by anisotropically etching a conformal layer of the constituent dielectric material and the one or more dielectric layers 10 may constitute an interlayer dielectric layer.

The gate cavity 12 may penetrate through the thickness of the one or more dielectric layers 10 to a top surface of a substrate 18, such as the top surface of a semiconductor fin. The gate cavity 12 may be formed by the removal of a sacrificial gate structure from the space between the dielectric spacers 17. The term “sacrificial gate structure” as used herein refers to a placeholder structure for a functional gate structure to be subsequently formed. The term “functional gate structure” as used herein refers to a permanent gate structure used to control output current (i.e., flow of carriers in the channel) of a field-effect transistor.

The gate dielectric layer 14 includes vertical sections arranged between the conductor layer 16 and the sidewalls 11 of the gate cavity 12 and a horizontal section arranged between the conductor layer 16 and the bottom surface 13 of the gate cavity 12. The gate dielectric layer 14 may be composed of a dielectric material, such as a high-k dielectric having a dielectric constant (i.e., permittivity) greater than the dielectric constant of silicon dioxide (SiO₂). High-k dielectric materials suitable for the gate dielectric layer 14 include, but are not limited to, a hafnium-based dielectric material like hafnium oxide (HfO₂), a layered stack of a hafnium-based dielectric material and another dielectric material (e.g., aluminum oxide (Al₂O₃)), or combinations of these and other dielectric materials, deposited by atomic layer deposition (ALD).

The conductor layer 16 may be composed of a work function metal deposited by physical vapor deposition (PVD) or chemical vapor deposition (CVD). The composition of the conductor layer 16 may be selected for forming a gate electrode of either an n-type field-effect transistor or a p-type field-effect transistor. In an embodiment, the work function metal of conductor layer 16 may be composed of titanium nitride (TiN) used in a gate stack forming a gate electrode of a p-type field-effect transistor, and may be patterned to remove the conductor layer from gate cavities (not shown) in regions used to fabricate n-type field-effect transistors.

With reference to FIG. 2 in which like reference numerals refer to like features in FIG. 1 and at a subsequent fabrication stage of the processing method, the conductor layer 16 is recessed and chamfered with an etching process that removes sections of the conductor layer 16 from a portion of the sidewalls 11 of the gate cavity 12. An etch mask 19 is applied to facilitate the chamfering of the conductor layer 16, and may include an organic planarization layer (OPL) material that is applied by spin-coating and recessed with reactive ion etching to a thickness that provides the desired amount of chamfering. The partial removal and pull down of the conductor layer 16 may be effective to reduce the contribution of the conductor layer 16 to the gate electrode and to lower its electrical resistance by replacing the removed portion with a conductor of lower electrical resistivity. After the conductor layer 16 is chamfered, the etch mask 19 is stripped by, for example, ashing with an oxygen plasma.

With reference to FIG. 3 in which like reference numerals refer to like features in FIG. 2 and at a subsequent fabrication stage of the processing method, the conductor layers 20, 22 are conformally deposited on the sidewalls 11 and bottom surface 13 of the gate cavity 12. The conductor layers 20, 22 cover the conductor layer 16 where present inside the gate cavity 12. The conductor layer 20 may be composed of one or more barrier metal layers and/or work function metal layers deposited by PVD or CVD. The conductor layer 22 may be composed of one or more work function metal layers deposited by PVD or CVD. Depending on the composition of the conductor layer 16, the composition of the conductor layers 20, 22 may be selected for forming a gate electrode of either an n-type field-effect transistor or a p-type field-effect transistor that is the complement of the field-effect transistor that includes conductor layer 16. In an embodiment, the conductor layer 20 may be a barrier metal layer composed of titanium nitride (TiN), and the conductor layer 22 may be a work function metal layer composed of titanium aluminum carbide (TiA1C) used in combination as a metal gate stack in the formation of a gate electrode of an n-type field-effect transistor. In an embodiment, a conventional barrier metal layer (e.g., TiN) is not formed on the one or more work function metals of the conductor layer 22.

A conductor layer 24 is formed that conformally covers the conductor layer 22 inside the gate cavity 12. The conductor layer 24 is composed of fluorine-free tungsten (W) formed by ALD using a tungsten-containing precursor source that does not contain fluorine as a component. The conductor layer 24 is formed in the same deposition tool as conductor layers 20, 22 such that an air break is not present between the successive depositions. The conductor layer 24 is formed in the metal gate stack as a replacement for a conventional barrier metal layer.

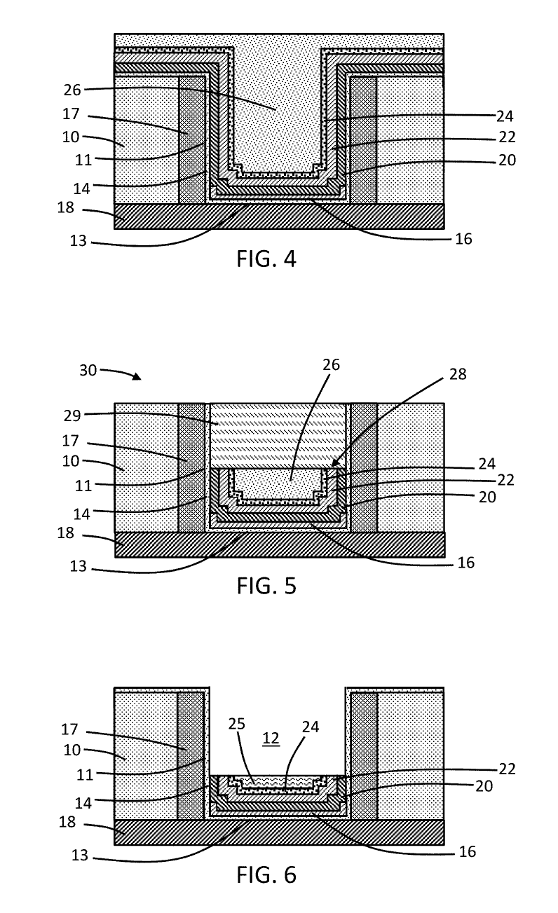

With reference to FIG. 4 in which like reference numerals refer to like features in FIG. 3 and at a subsequent fabrication stage of the processing method, a conductor layer 26 is formed that fills the open space inside the gate cavity 12 that is not occupied by the conductor layers 16, 20, 22, 24 and gate dielectric layer 14. The conductor layer 26 is composed of a conductor, such as tungsten (W) deposited by CVD and may be formed using a tungsten-containing precursor source (e.g., WF₆) that contains fluorine as a component. The conductor layer 26 is formed in a different deposition tool than the conductor layer 24 and the depositions occur with an air break between the successive depositions. The conductor layers 24, 26, which are composed of the same material and collectively define a fill layer that is composed of tungsten, are arranged in direct contact with the conductor layer 22 without the intervening presence of a barrier metal layer, which represents a difference relative to arrangements of work function metal and fill metal layers in conventional metal gate constructions. The material forming the conductor layers 24, 26 has a lower electrical resistivity than the materials of the conductor layers 20, 22. The conductor layer 24 covers the conductor layer 22 during the chemical vapor deposition of conductor layer 26 and blocks the passage of fluorine produced as a byproduct gas.

With reference to FIG. 5 in which like reference numerals refer to like features in FIG. 4 and at a subsequent fabrication stage of the processing method, the conductor layer 26 and the conductor layers 20, 22, 24 are planarized using a chemical-mechanical polishing (CMP) process to provide a top surface that is coplanar relative to the one or more dielectric layers 10. After planarization, the conductor layers 20, 22, 24, 26 are recessed within the gate cavity 12 using an etching process to define a gate electrode in the form of a functional gate structure 28. In an embodiment, the conductor layers 20, 22, 24, 26 may be concurrently recessed with the same etching process such that the conductor layers 20, 22 are not chamfered. The functional gate structure 28 may constitute a metal gate electrode of a field-effect transistor 30 and, in an embodiment, the field-effect transistor 30 is a p-type field-effect transistor in which the functional gate structure 28 includes one or more work function metals that are characteristic of a p-type field-effect transistor.

The space opened in the gate cavity 12 may be filled by a dielectric cap 29 composed of, for example, silicon nitride (Si₃N₄) deposited by CVD and planarized with CMP. The dielectric cap 29 may be subsequently used in a self-aligned contact process that is performed during MOL processing to contact the functional gate structure 28. The dielectric cap 29 has an exposed top surface and a bottom surface that is in direct contact with the conductor layers 20, 22, 24, 26.

Middle-of-line (MOL) and back-end-of-line (BEOL) processing follow, which includes formation of contacts and wiring for the local interconnect structure overlying the device structure, and formation of dielectric layers, via plugs, and wiring for an interconnect structure coupled by the interconnect wiring with the functional gate structure 28 and other elements (e.g., source/drain regions) of the field-effect transistor 30.

The embodiments of the invention may mitigate the formation of keyholes or voids during the final recess before the formation of the dielectric cap 29 because a conductor layer 26 comprised of tungsten formed by CVD is the primary material that is recessed. The result is an improved yield in comparison with only recessing work function metals in the final recess, as is conventional. The embodiments of the invention may increase the space available in the gate cavity 12 for low-resistivity tungsten, which may result in improved device performance. The increased space is the result, at least in part, of inserting a chamfer after the conductor layer 16 before the conductor layers 20, 22 are formed, and replacing the conventional barrier metal layer (e.g., TiN) with the conductor layer 24 that is composed of a lower resistivity material, e.g., fluorine-free tungsten.

An n-type field-effect transistor 30 may exhibit a reduced threshold voltage because the gate stack including the conductor layers 20, 22 can be kept thin by replacing the capping barrier metal layer with the conductor layer 24 composed of fluorine-free tungsten. The conductor layer 24 composed of fluorine-free tungsten may be effective to prevent fluorine from attacking one or more of the conductor layers 20, 22 (e.g., Al-containing titanium aluminum carbide (TiA1C) in conductor layer 22). In addition, the ability to omit the chamfer of the conductor layers 20, 22 avoids the need to remove an associated etch mask, which could otherwise introduce oxygen originating from an oxygen plasma as an impurity into conductor layer 20 and/or conductor layer 22.

With reference to FIG. 6 in which like reference numerals refer to like features in FIG. 3 and at a subsequent fabrication stage of the processing method in accordance with alternative embodiments of the invention, the deposition of the conductor layer 24 may be preceded by an optional hydrogen plasma treatment in the same chamber in which the conductor layer 24 is deposited. The conductor layers 20, 22, 24 are recessed and chamfered within the gate cavity 12 using one or more etching processes. An etch mask 25 is applied prior to the chamfering of the conductor layers 20, 22, 24, and may include an organic planarization layer (OPL) material that is applied by spin-coating and recessed with reactive ion etching to a thickness that provides the desired amount of chamfering. The gate dielectric-covered sidewalls 11 of the gate cavity 12 are exposed above the level of the recessed conductor layers 20, 22, 24. The etch mask 25 is stripped by, for example, ashing with an oxygen plasma after the conductor layers 20, 22, 24 are chamfered.

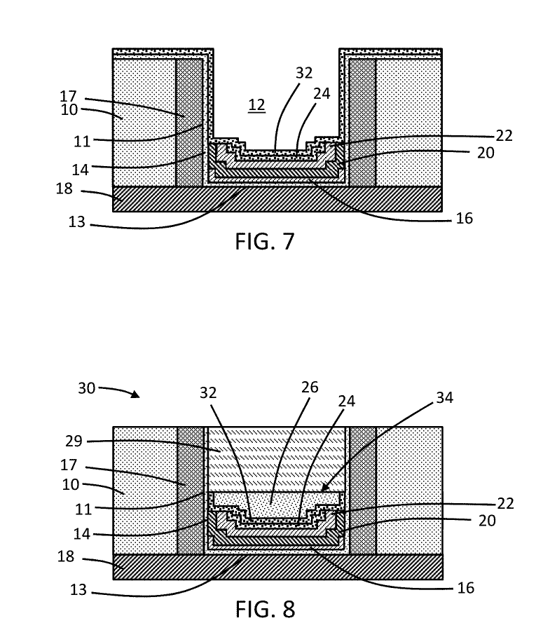

With reference to FIG. 7 in which like reference numerals refer to like features in FIG. 6 and at a subsequent fabrication stage of the processing method, a conductor layer 32 is formed that conformally covers the exposed surfaces of the conductor layers 20, 22, 24 inside the gate cavity 12 and the gate dielectric-covered sidewalls 11 of the gate cavity 12 above the level of the recessed conductor layers 20, 22, 24. The conductor layer 32 is composed of fluorine-free tungsten (W) formed by ALD using a tungsten-containing precursor source that does not contain fluorine as a component. The conductor layer 32 is formed in the metal gate stack as a replacement for a conventional barrier metal layer.

With reference to FIG. 8 in which like reference numerals refer to like features in FIG. 7 and at a subsequent fabrication stage of the processing method, the conductor layer 26 is formed as a fill layer that fills the open space inside the gate cavity 12 that is not occupied by the conductor layers 16, 20, 22, 32 and gate dielectric layer 14 in order to complete the formation of a gate electrode 34 of the field-effect transistor 30. The conductor layer 26 is formed in a different deposition tool than the conductor layer 32 and an air break occurs between the successive depositions. The conductor layers 26, 32, which are composed of the same material and collectively define a fill layer that is composed of tungsten, are arranged in direct contact with the conductor layer 22 without the intervening presence of an intervening barrier metal layer, which represents a difference relative to conventional arrangements of work function metal and fill metal in gate stacks. The conductor layer 26 is recessed and the space opened in the gate cavity 12 above the recessed conductor layer 26 is filled by the dielectric cap 29.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for forming a field-effect transistor, the method comprising:
forming a gate cavity in a dielectric layer that includes a bottom surface and a plurality of sidewalls extending to the bottom surface;
forming a gate dielectric layer at the sidewalls and the bottom surface of the gate cavity;
depositing a first work function metal layer on the gate dielectric layer at the sidewalls and the bottom surface of the gate cavity; and
after the first work function metal layer is deposited, forming a fill metal layer inside the gate cavity,
wherein the fill metal layer is formed in direct contact with the first work function metal layer.

2. The method of claim 1 wherein forming the fill metal layer inside the gate cavity that is in direct contact with the first work function metal layer comprises:
conformally depositing a first fluorine-free tungsten layer on the first work function metal layer.

3. The method of claim 2 wherein forming the fill metal layer inside the gate cavity that is in direct contact with the first work function metal layer further comprises:
depositing a conductor layer on the first fluorine-free tungsten layer,
wherein the conductor layer fills empty space remaining inside the gate cavity after the first fluorine-free tungsten layer is deposited.

4. The method of claim 3 wherein the first fluorine-free tungsten layer is formed using atomic layer deposition and a first precursor source that is free of fluorine, and the conductor layer is formed using chemical vapor deposition and a second precursor source that includes fluorine.

5. The method of claim 2 further comprising:
chamfering the first fluorine-free tungsten layer and the first work function metal layer; and
conformally depositing a second fluorine-free tungsten layer on the first work function metal layer and the first fluorine-free tungsten layer.

6. The method of claim 2 wherein the first fluorine-free tungsten layer is formed using atomic layer deposition and a precursor source that is free of fluorine.

7. The method of claim 2 wherein the first fluorine-free tungsten layer and the first work function metal layer are deposited in the same deposition tool without an air break.

8. The method of claim 1 wherein the bottom surface of the gate cavity opens to a semiconductor fin.

9. The method of claim 1 further comprising:
before forming the first work function metal layer, forming a second work function metal layer on the gate dielectric layer at the sidewalls and the bottom surface of the gate cavity after forming the gate dielectric layer; and
before forming the first work function metal layer, chamfering the second work function metal layer.

10. The method of claim 1 further comprising:
concurrently recessing the fill metal layer and the first work function metal layer; and
forming a dielectric cap inside the gate cavity after concurrently recessing the fill metal layer and the first work function metal layer.

11. The method of claim 10 wherein the first work function metal layer and the fill metal layer are in direct contact with the dielectric cap.

12. A structure for a field-effect transistor, the method comprising:
a dielectric layer including a gate cavity with a bottom surface and a plurality of sidewalls that extend to the bottom surface;
a gate dielectric layer at the sidewalls and the bottom surface of the gate cavity;
a first work function metal layer on the gate dielectric layer at the sidewalls and the bottom surface of the gate cavity; and
a fill metal layer inside the gate cavity, the fill metal layer in a directly contacting relationship with the first work function metal layer.

13. The structure of claim 12 wherein the fill metal layer includes a first fluorine-free tungsten layer arranged on the first work function metal layer.

14. The structure of claim 13 wherein the fill metal layer further includes a conductor layer on the first fluorine-free tungsten layer, the conductor layer arranged to fill empty space inside the gate cavity interior of the first fluorine-free tungsten layer.

15. The structure of claim 13 further comprising:
a second fluorine-free tungsten layer on the first work function metal layer and the first fluorine-free tungsten layer.

16. The structure of claim 15 wherein the first fluorine-free tungsten layer is arranged between the second fluorine-free tungsten layer and the first work function metal layer.

17. The structure of claim 13 wherein the first work function metal layer is composed of titanium aluminum carbide.

18. The structure of claim 12 further comprising:
a semiconductor fin,
wherein the bottom surface of the gate cavity opens to the semiconductor fin.

19. The structure of claim 12 further comprising:
a second work function metal layer at the sidewalls and the bottom surface of the gate cavity, the second work function metal layer arranged between the gate dielectric layer and the first work function metal layer; and
a barrier metal layer arranged between the first work function metal layer and the second work function metal layer.

20. The structure of claim 12 further comprising:
a dielectric cap inside the gate cavity above the fill metal layer,
wherein the first work function metal layer and the fill metal layer have a directly contacting relationship with the dielectric cap.
